(19) United States
(12) Patent Application Publication
(10) Pub. No.: US 2018/0157369 A1
(43) Pub. Date: Jun. 7, 2018

(54) FLEXIBLE TOUCH PANEL

(71) Applicant: Sichuan Longhua Film Co., Ltd, Mianyang (CN)

(72) Inventors: Rui-Min Diao, Mianyang (CN); Yao-Chang Wang, Zhubei City (TW); Yi-Ping Hsieh, Zhudong Township (TW)

(21) Appl. No.: 15/823,390

(22) Filed: Nov. 27, 2017

(30) Foreign Application Priority Data
Dec. 6, 2016 (CN) 201611108765.2

(51) Int. Cl. G06F 3/041; H01L 27/32

(52) U.S. Cl. CPC G06F 3/0416; G06F 2203/04102; H01L 27/323; G06F 3/0412

(57) ABSTRACT

A flexible touch panel includes a display unit, a touch sensing unit and a protective layer. The touch sensing unit is bounded to the display unit, and includes two touch control circuit layers and a waveplate. The waveplate is disposed between two touch control circuit layers, and includes a first plane and a second plane opposite to the first plane. One of the touch control circuit layers is formed on the first plane. The protective layer is bounded to the touch sensing unit, and the touch sensing unit is disposed between the display unit and the protective layer.

### FIELD OF THE INVENTION

The invention relates to a display panel, and more particularly to a flexible touch panel.

### BACKGROUND OF THE INVENTION

Organic light-emitting diode (OLED) display panel has a slim feature, so it has the potential to develop into a flexible display panel. OLED display panel itself does not have the touch sensing function, and to make OLED display panel with touch sensing function, it is needed to incorporate a touch module into the OLED display panel, so as to perform a flexible touch panel. However, increasing the touch module will increase the overall thickness of the flexible touch panel, which may affect flexibility.

### SUMMARY OF THE INVENTION

The invention provides a flexible touch panel, which has a decreased overall thickness to help improve flexibility.

The invention provides a flexible touch panel, comprising a display unit; a touch sensing unit, bonded to the display unit and comprising two touch control circuit layers; a waveplate, disposed between the two touch control circuit layers, and comprising a first plane and a second plane opposite to the first plane, wherein one of the touch control circuit layers is formed above the first plane; and a protective layer, bounding to the touch sensing unit, wherein the touch sensing unit is disposed between the display unit and the protective layer.

In one embodiment of the invention, one of the touch control circuit layers contacts the first plane.

In one embodiment of the invention, the display unit is an OLED display panel.

In one embodiment of the invention, the waveplate is a quarter-wave plate and the protective layer is a linear polarizer.

In one embodiment of the invention, the touch sensing unit further comprises a barrier layer, the barrier layer is bounded to the second plane, and the touch control circuit layers contact the waveplate and the barrier layer, respectively.

In one embodiment of the invention, the barrier layer comprises SiO₂ or SiN.

In one embodiment of the invention, the flexible touch panel further comprises a barrier layer, wherein the display unit is bounded to the barrier layer, and the barrier layer is disposed between the display unit and the touch sensing unit.

In one embodiment of the invention, a sum of a thickness of the touch sensing unit and a thickness of the protective layer is less than 200 μm.

In one embodiment of the invention, a sum of a thickness of the touch sensing unit and a thickness of the protective layer is less than or equal to 40 μm.

As the touch sensing unit includes waveplate, it not only has the touch sensing function, but also has ability to weaken or eliminate the reflection of the ambient light. By this touch sensing unit, the present invention enables the flexible touch panel to have a reduced overall thickness to help improve flexibility.

The foregoing description is merely an overview of the technical solution of the present invention. In order to enable a clearer understanding of the technical means of the present invention, and thus it can be implemented in accordance with the teachings of the present invention, and to enable the above features and advantages of the present invention to be more clearly understood, the embodiments are described in detail with reference to the accompanying drawings.

### BRIEF DESCRIPTION OF THE DRAWINGS

FIG. 1 is a schematic cross-sectional view of a flexible touch panel in accordance with a first embodiment of the invention.

FIG. 2 is a schematic cross-sectional view of a flexible touch panel in accordance with a second embodiment of the invention.

FIG. 3 is a schematic cross-sectional view of a flexible touch panel in accordance with a third embodiment of the invention.

### DETAILED DESCRIPTION OF PREFERRED EMBODIMENTS

In order to further illustrate the technical means of the present invention, the specific embodiments, structures, features and effects thereof according to the present invention will be described in detail with reference to the accompanying drawings and examples.

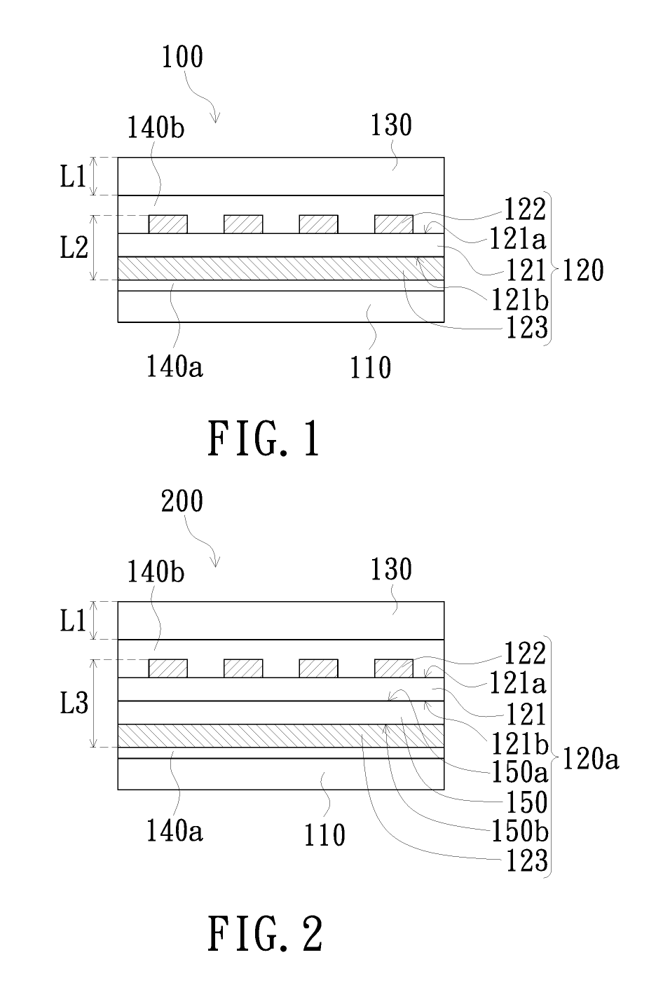

Referring to FIG. 1, the flexible touch panel 100 of the first embodiment includes a display unit 110, a touch sensing unit 120, and a protective layer 130, wherein the display unit 110, the touch sensing unit 120 and the protective layer 130 are flexible, so that flexible touch panel 100 may also be flexible. The touch sensing unit 120 is disposed between the display unit 110 and the protective layer 130, wherein the touch sensing unit 120 is bounded to the display unit 110, and the protective layer 130 is bounded to the touch sensing unit 120.

The flexible touch panel 100 may also include two optical glue layers 140a and 140b comprising optical clear adhesive (OCA). The optical glue layer 140a is connected the touch sensing unit 120 to the display unit 110 and the other optical glue layer 140b is connected between the protective layer 130 and the touch sensing unit 120. In addition, the display unit 110 may be an OLED display panel, and the protective layer 130 may be a linear polarizer, wherein the protective layer 130 may be primarily made of a polymeric material such as polycarbonate (PC), polyethylene terephthalate (PET), polyimide (PI) or epoxy.

The touch sensing unit 120 includes the waveplate 121 and two touch control circuit layers 122 and 123. The waveplate 121 has a first plane 121a and a second plane 121b opposite to the first plane 121a, wherein the touch control circuit layer 122 is formed on the first plane 121a and the touch control circuit layer 123 is formed on the second plane 121b. Therefore, the waveplate 121 is disposed between the two touch control circuit layers 122 and 123.

The touch control circuit layers 122 and 123 may be directly formed on the first plane 121a and the second plane 121b, respectively, so that the touch control circuit layers 122 and 123 may contact the first plane 121a and the second plane 121b, respectively. In addition, the constituent materials of the touch control circuit layers 122 and 123 may be indium tin oxide (ITO) or indium zinc oxide (IZO), and the touch control circuit layers 122 and 123 may be formed by sputtering.

The waveplate 121 may be a quarter-wave plate having a slow axis and the main constituent material of the waveplate 121 may be the same as the protective layer 130. When the protective layer 130 is a linear polarizer and the waveplate 121 is a quarter-wave plate, the angle between the polarization direction of the protective layer 130 and the slow axis is 45 degrees so that the protective layer 130 and the waveplate 121 can form a circular polarizer. When the ambient light enters the flexible touch panel 100, the light passes through the protective layer 130 and the waveplate 121, and then changes to circular polarized light and enters the display unit 110.

As stated above, the display unit 110 will reflect this circular polarized light, so that the circular polarized light may pass through the waveplate 121. Once the circular polarized light has passed through the waveplate 121, it becomes a linear polarized light with a polarization direction perpendicular to the polarization direction of the protective layer 130, so that the linear polarized light is blocked by the protective layer 130. It can be seen that the waveplate 121 and the protective layer 130 can attenuate or eliminate the light reflected by the flexible touch panel 100, thereby helping the image displayed by the flexible touch panel 100 to be disturbed or destroyed by the reflected light.

Since the touch control circuit layers 122 and 123 are directly formed on both sides of the waveplate 121, the touch control circuit layers 122 and 123 are in contact with the first plane 121a and the second plane 121b, respectively, and the waveplate 121 and the protective layer 130 can attenuate or eliminate the reflected light. Accordingly, the touch sensing unit 120 not only has the touch sensing function, but also has the advantage of enhancing the image.

In contrast, the existing touch module, which is typically used to mount the display panel, does not have any delay function in the light phase, so that most of the touch panels also need to be fitted with an extra waveplate to weaken or eliminate the reflected light. Compared to the existing touch panel, the touch sensing unit 120 can replace the waveplate within the existing touch panel because the touch sensing unit 120 has the touch sensing function and the advantage of enhancing the image, causing the flexible touch panel 100 to have reduced overall thickness and fewer layers.

The touch sensing unit 120 has a thickness L2 and the protective layer 130 has a thickness L1 in which both the thickness L1 and the thickness L2 may be less than 200 μm and may even be less than or equal to 40 μm. When both the thickness L1 and the thickness L2 are between 200 μm and 40 μm, the flexible touch panel 100 is sufficient to facilitate flexing. When the thickness L1 and the thickness L2 are less than 40 μm, it is more advantageous to make the flexible touch panel 100 have the characteristics of repeated deflection.

Referring to FIG. 2, the flexible touch panel 200 of the second embodiment is similar to the structure of the flexible touch panel 100 of the first embodiment, and both of them have the same advantages, so that the same feature is not repeated in principle, and the following descriptions will be mainly focus on the difference between the touch panels 200 and 100, that is, the touch sensing unit 120a of the flexible touch panel 200.

In the second embodiment, the touch sensing unit 120a, in addition to the waveplate 121, the touch control circuit layer 122, and the touch control circuit layer 123, further includes a barrier layer 150, which is bonded to the second plane 121b of the waveplate 121. That is, the barrier layer 150 is bonded to the waveplate 121 near the side of the display unit 110. The barrier layer 150 has a first plane 150a and a second plane 150b corresponding to the first plane 150a, where the second plane 121b is combined with the first plane 150a. The touch control circuit layers 122 and 123 are respectively formed directly on the first plane 121a and the second plane 150b, i.e. the touch control circuit layers 122 and 123 respectively contact the waveplate 121 and the barrier layer 150.

The barrier layer 150 is capable of blocking moisture and oxygen from entering the display unit 110, and thus reduces or avoids the adverse effects of moisture and oxygen on the display unit 110 and extends the life of the display unit 110. The barrier layer 150 may be formed by stacking a plurality of layers of inorganic material or a plurality of layers of organic and inorganic materials, wherein the inorganic material may be SiO₂, SiN or a combination of the two materials, and the organic material is, for example, polycarbonate ester (PC), polyethylene terephthalate (PET), polyimide (PI) or epoxy. In addition, the touch sensing unit 120a has a thickness L3, and the thickness L1 and the thickness L3 may be less than 200 μm and may even be less than or equal to 40 μm.

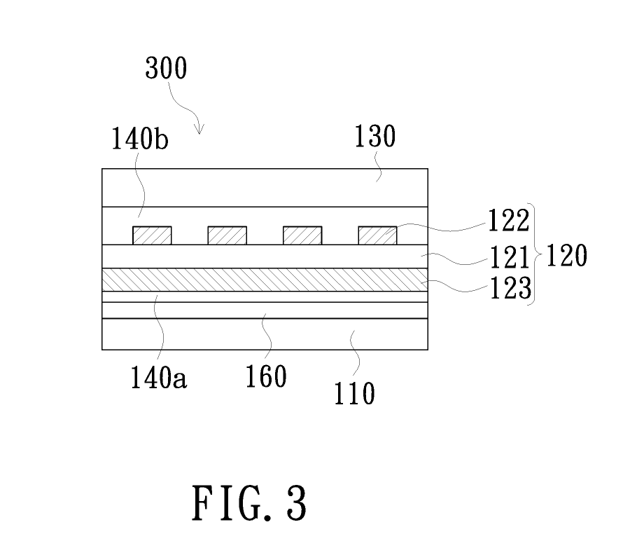

Referring to FIG. 3, the flexible touch panel 300 of the third embodiment is similar to the structure of the flexible touch panel 200 of the second embodiment, and both of them have the same advantages, so that the same feature is not repeated in principle, and the following description will be mainly focus on the differences between the touch panels 200 and 300.

Unlike the touch panel 200, in the third embodiment, the flexible touch panel 300 includes a touch sensing unit 120 that does not contain a barrier layer, but the flexible touch panel 300 further includes a barrier layer 160 that is bonded to the display unit 110, it is, for example, a single layer or multilayer film, and is disposed between the display unit 110 and the touch sensing unit 120. In addition, the barrier layer 160 may be made of SiO₂ or SiN, and may be formed by chemical vapor deposition (CVD).

In summary, the touch sensing unit of the present invention is formed by forming touch control circuit layers directly on the waveplate, so that the touch sensing unit not only has the function of touch sensing, but also has the ability to weaken or eliminate the reflection of the ambient light. Accordingly, the touch sensing unit disclosed in the above embodiments of the present invention can replace at least one optical film (e.g., a waveplate) to cause the flexible touch panel to have a reduced overall thickness, and a smaller number of layers.

The foregoing is merely illustrative of the embodiments of the present invention and is not intended to be limiting of the present invention. While the invention has been disclosed by way of example, it is not intended to be limiting of the invention. It is to be understood that within the scope of the technical solutions of the present invention, the equivalent embodiments of the present invention may be modified and modified to be equivalent to those skilled in the art without departing from the scope of the technical solutions of the present invention. Any simple modifications, equivalent variations and modifications of the embodiments are within the scope of the technical solutions of the present invention.

What is claimed is:

1. A flexible touch panel, comprising:
a display unit;
a touch sensing unit, bonded to the display unit and comprising:
two touch control circuit layers;
a waveplate, disposed between the touch control circuit layers, and comprising a first plane and a second plane opposite to the first plane, wherein one of the touch control circuit layers is formed above the first plane; and
a protective layer, bounding to the touch sensing unit, wherein the touch sensing unit is disposed between the display unit and the protective layer.

2. The flexible touch panel according to claim 1, wherein one of the touch control circuit layers contacts the first plane.

3. The flexible touch panel according to claim 1, wherein the display unit is an OLED display panel.

4. The flexible touch panel according to claim 1, wherein the waveplate is a quarter-wave plate and the protective layer is a linear polarizer.

5. The flexible touch panel according to claim 1, wherein the touch sensing unit further comprises a barrier layer, the barrier layer is bounded to the second plane, and the touch control circuit layers contact the waveplate and the barrier layer, respectively.

6. The flexible touch panel according to claim 5, wherein the barrier layer comprises SiO₂ or SiN.

7. The flexible touch panel according to claim 1, further comprises a barrier layer, wherein the display unit is bounded to the barrier layer, and the barrier layer is disposed between the display unit and the touch sensing unit.

8. The flexible touch panel according to claim 7, wherein the barrier layer comprises SiO₂ or SiN.

9. The flexible touch panel according to claim 1, wherein a sum of a thickness of the touch sensing unit and a thickness of the protective layer is less than 200 μm.

10. The flexible touch panel according to claim 1, wherein a sum of a thickness of the touch sensing unit and a thickness of the protective layer is less than or equal to 40 μm.
